(19) United States
(12) Patent Application Publication
(10) Pub. No.: US 2025/0218940 A1
(43) Pub. Date: Jul. 3, 2025

(54) SEMICONDUCTOR STRUCTURE AND METHOD OF FABRICATING A SEMICONDUCTOR STRUCTURE

(71) Applicant: Taiwan Semiconductor Manufacturing Company, Ltd., Hsinchu (TW)

(72) Inventors: Wen-Ling Chang, Miaoli County (TW); Cheng-Hsien WU, Hsinchu (TW); Man-Yun WU, Hsinchu (TW); Yu-Bey Wu, Hsinchu City (TW); Wen-Chiung Tu, New Taipei City (TW); Chen-Chiu Huang, Taichung City (TW); Dian-Hau Chen, Hsinchu (TW); Chung-Yi Lin, Hsinchu County (TW); Ching-Feng Sung, Hsinchu County (TW); Hsiu-Chia Kuo, Hsinchu County (TW)

(73) Assignee: Taiwan Semiconductor Manufacturing Company, Ltd., Hsinchu (TW)

(21) Appl. No.: 18/396,713

(22) Filed: Dec. 27, 2023

(51) Int. Cl. H01L 23/528; H01L 23/00

(52) U.S. Cl. CPC H01L 23/5283; H01L 24/08; H01L 2224/08145

(57) ABSTRACT

A method of fabricating a semiconductor structure provided herein includes providing a thick-metal density range for a model structure, wherein the model structure includes a wafer substrate, and layers of metal patterns stacking on the wafer substrate; modifying the thick-metal density range to constrain a warpage range of the model structure toward a target range of warpage; and fabricating the semiconductor structure by forming the layers of metal patterns on the wafer substrate, wherein a thick-metal layer among the layers of metal patterns is formed based on the modified thick-metal density range, and a thickness of the thick-metal layer is twice or more of a thickness of one of the layers of metal patterns next to the thick-metal layer. A semiconductor structure fabricating by using the above method is further provided.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. As semiconductor technologies further advance, stacked semiconductor devices, e.g., 3D integrated circuit (3DIC) packages, have emerged as an effective alternative to further reduce the physical size of a semiconductor device.

In a stacked semiconductor device, active circuits such as logic, memory, processor circuits, and the like are manufactured on different semiconductor wafers and integrated to one (3DIC) package through suitable bonding techniques. The high level of integration of advanced packaging technologies enables production of semiconductor devices with enhanced functionalities and small footprints, which is advantageous for small form factor devices such as mobile phones, tablets and digital music players.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a semiconductor device in accordance with some embodiments of the disclosure.

FIG. 2 schematically illustrates a semiconductor device in accordance with some embodiments of the disclosure.

FIG. 3 is schematically flow chart of fabricating a semiconductor structure in accordance with some embodiments.

FIG. 4 schematically illustrates a top view of a thick-metal layer in the semiconductor structure in accordance with some embodiments of the disclosure.

FIG. 5 schematically illustrates a portion of a semiconductor structure in accordance with some embodiments of the disclosure.

FIG. 6 schematically illustrates a portion of a semiconductor structure in accordance with some embodiments of the disclosure.

FIG. 7 schematically illustrates a portion of a semiconductor structure in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be valueing. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Packages and the methods of forming the same are provided in accordance with various exemplary embodiments. The intermediate stages of forming the packages are illustrated. The variations of the embodiments are discussed. Throughout the various views and illustrative embodiments, like reference numbers are used to designate like elements.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

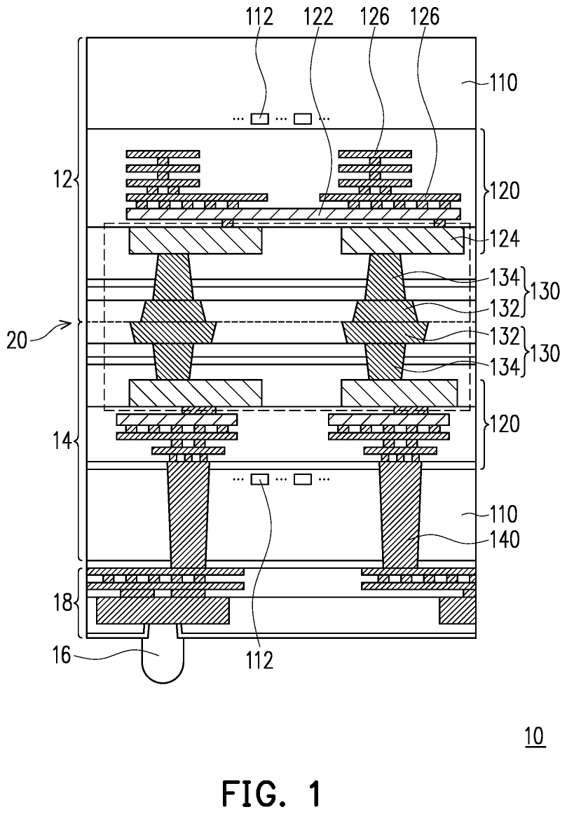

FIG. 1 schematically illustrates a semiconductor device in accordance with some embodiments of the disclosure. A semiconductor device 10 includes two semiconductor structures 12 and 14 bonded to each other, and external connectors 16. In some embodiments, each of the semiconductor structures 12 and 14 can include a substrate 110 that is a portion of a wafer substrate, a plurality of layers of metal patterns 120, and a plurality of bonding features 130. The layers of metal patterns 120 are sequentially stacked on the substrate 110 and the bonding features 130 are disposed on the layers of metal patterns 120 for in contact with another structure. In some embodiments, each of the semiconductor structures 12 and 14 further includes circuitry components 112 such as transistors or the like disposed on the substrate 110 at a side of the substrate 110 adjacent to the layers of metal patterns 12. The layers of metal patterns 120 establishes the electrical transmission paths for the circuitry components 112. The bonding features 130 include the bonding pads 132 and the bonding vias 134, and the bonding vias 134 is disposed between the bonding pads 132 and the layers of metal patterns 120. The semiconductor structure 12 or 14 further includes dielectric structure including multiple dielectric layers for separating different patterns of the layers of metal patterns 120, and the bonding features 130. The external connector 16 for connecting to external component/device and the semiconductor structure 12 bonded to the semiconductor structure 14 are disposed at opposite sides of the substrate 110 of the semiconductor structure 14, and thus the semiconductor structure 14 further includes through substrate vias 140 that extend through the thickness of the substrate 110 and establish the signal transmission features passing through the substrate 110.

In the embodiment, the semiconductor structure 12 and the semiconductor structure 14 are bonded to each other in a face to face manner that the circuitry components 112 of the substrate 110 in the semiconductor structure 12 is disposed on the (front) side of the substrate 110 faces to the (front) side of the substrate 110 having the circuitry components 112 in the semiconductor structure 14. In some embodiments, the bonding interface 20 between the semiconductor structure 12 and the semiconductor structure 14 is a metal to metal and dielectric to dielectric bonding interface. In the embodiment, the semiconductor device 10 further includes a redistribution wiring structure 18 disposed at a (back) side of the semiconductor structure 14, opposite to the semiconductor structure 12. The redistribution wiring structure 18 is located between the external connectors 16 and the semiconductor structure 14. In the semiconductor structure 14, the through substrate vias 140 are connected between the layers of metal patterns 120 at the front side and the redistribution wiring structure 18 at the back side.

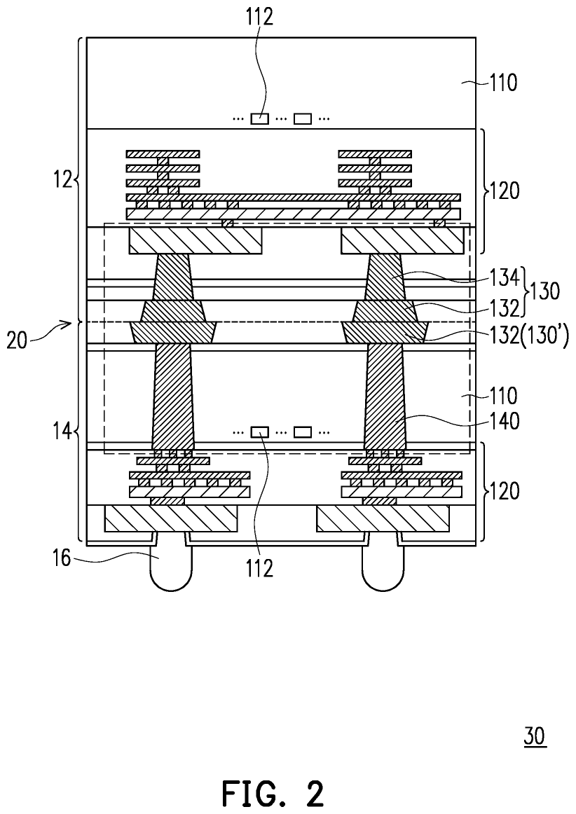

FIG. 2 schematically illustrates a semiconductor device in accordance with some embodiments of the disclosure. A semiconductor device 30 in FIG. 2 includes two semiconductor structures 12 and 14 bonded to each other, and external connectors 16. The semiconductor structure 12 is similar to that described in FIG. 1 and includes a substrate 110, layers of metal patterns 120, and bonding features 130. The semiconductor structure 14 is also similar to that described in FIG. 1 and includes a substrate 110, layers of metal patterns 120, bonding features 130′ and through substrate vias 140. Each of the semiconductor structures 12 and 14 further includes dielectric structure including multiple dielectric layers separating different patterns of the layers of metal patterns 120 and the bonding features 130/130′.

In the semiconductor device 30, each of the semiconductor structures 12 and 14 further includes circuitry components 112. The substrate 110 of the semiconductor structure 12 is oriented that the circuitry components 112 face the external connectors 16 and the substrate 110 of the semiconductor structure 14 is also oriented that the circuitry components 112 face the external connectors 16, such that the semiconductor structure 12 and the semiconductor structure 14 are bonded to each other in a face to back manner. In addition, the bonding features 130′ of the semiconductor structure 140 in the semiconductor device 14 may be implemented by solely the bonding pads 132, but the disclosure is not limited thereto.

In the semiconductor structures 12 of both the semiconductor devices 10 and 30 and the semiconductor structure 14 of the semiconductor device 10, the bonding vias 134 are disposed on the layers of metal patterns 120 and the bonding pads 132 are disposed on terminals of the bonding vias 134. In the semiconductor structure 14 of the semiconductor device 30, the bonding pads 132 are disposed to connect to the through substrate vias 140. The bonding pads 132 on the semiconductor structure 12 and the bonding pads 132 on the semiconductor structure 14 are in contact with each other. In some embodiments, the bonding pads 132 on the semiconductor structure 12 and the bonding pads 132 on the semiconductor structure 14 are made of the same material and the boundary between the bonding pads 132 on the semiconductor structure 12 and the bonding pads 132 on the semiconductor structure 14 may hardly be determined after bonded. In some embodiments, the bonding pads 132 on the semiconductor structure 12 and the bonding pads 132 on the semiconductor structure 14 may have different lateral dimensions to form a step-like structure that helps to determine the bonding interface 20. In some embodiments, the bonding pads 132 on the semiconductor structure 12 and the bonding pads 132 on the semiconductor structure 14 may not be aligned perfectly to form a staggered structure which helps to determine the bonding interface 20.

In some embodiments, the layers of metal patterns 120 in each of the semiconductor structures 12 and 14 in both semiconductor devices 10 and 30 can be implemented by similar or the same design depicted in the following descriptions. In some embodiments, the layers of metal patterns 120 are sequentially disposed on a front side of the substrate 110 having the circuitry components 112 and include a first thick-metal layer 122, a second thick-metal layer 124 and other metal layers 126. In each of the semiconductor structures 12 and 14, the metal layers 126 are more adjacent to substrate 110 than the first thick-metal 122 and the second thick-metal layer 124. The first thick-metal layer 122 and the second thick-metal layer 124 are the thickest two layers among the layers of metal patterns 120.

In some embodiments, the first thick-metal layer 122 and the metal layers 126 construct an interconnect structure for the semiconductor structure 12 or the semiconductor structure 14 and there are totally 13 to 21 metallic layers for constructing the interconnect structure in some embodiments, but the disclosure is not limited thereto. In some embodiments, the thickness of the first thick-metal layer 122 is greater than any of the metal layers 126. The first thick-metal layer 122 can be the thickest metallic layer of the interconnect structure. In some embodiments, the thickness of the first thick-metal layer 122 is twice or more of the thickness of one of the metal layers 126 next to the first thick-metal layer 122. In some embodiments, the thickness of the first thick-metal layer 122 is in a range of 8,000 Å to 12,000 Å and the thickness of each of the metal layers 126 is in a range of greater than 0 Å to 3,000 Å.

In some embodiments, each of the metallic layers in the interconnect structure establishing a plurality of signal transmission features arranged at a prescribed pitch that is greater than 126 nm. In some embodiments, metal patterns in the layers of metal patterns 120 are arranged in a pitch that the pitch of one layer of metal pattern 120 more adjacent to the substrate 110 is smaller than the pitch of another layer of metal pattern 120 further from the wafer substrate 110. The pitch of the signal transmission features established by the first thick-metal layer 122 can be greater than the pitch of the signal transmission features established by any of the metal layers 126. In some embodiments, the pitch of the signal transmission features established by the first thick-metal layer 122 can be in a range of 700 nm to 2,000 nm. In some embodiments, the pitch of the signal transmission features of the metal layer 126 most adjacent to the substrate 110 can be smaller than 150 nm and greater than 126 nm. In some embodiments, the metallic layers in the interconnect structure include a metal or metal alloy such as copper (Cu), cobalt (Co), nickel (Ni), aluminum (Al), or combinations thereof.

The second thick-metal layer 126 in the semiconductor structure 12 or 14 is disposed on the first thick-metal layer 122 to rearrange the electric connection of the layers of metal patterns 120 and provide the contact features for the bonding features 130. In some embodiments, the second thick-metal layer 124 may have a thickness twice or more of the thickness of the first thick-metal layer 122. For example, the thickness of the second thick-metal layer 124 may be ranged from about 25,000 Å to about 30,000 Å. In some embodiments, the thickness of the second thick-metal layer 124 may be about 28,000 Å. In some embodiments, the second thick-metal layer 124 establishes signal transmission features and the pitch of the signal transmission features of the second thick-metal layer 124 can be greater than 720 nm, but the disclosure is not limited thereto.

In some embodiments, the material of the first thick-metal layer 122 and the second thick-metal layer 124 can have a modulus greater than 100 Gpa and a coefficient of thermal expansion (CTE) smaller than 20×10⁻⁶/K@20° C. In some embodiments, the material of the first thick-metal layer 122 and the second thick-metal layer 124 can include Cu which has a modulus of 110 Gpa and have a coefficient of thermal expansion (CTE) of 17×10⁻⁶/K@20° C. The semiconductor device 10 and the semiconductor device 30 are formed by bonding two semiconductor structures 12 and 14 to each other through the bonding features 130/130′ formed integrally on the substrate 110 without using external bumps, conductor pillars, or the like. The warpage taken place during the fabrication of the semiconductor structure 12 or 14 during the wafer level process influences on the bonding yield. In the semiconductor structures 12 and 14, the first thick-metal layer 122 and the second thick-metal layer 124 can be more sensitive to warpage cause by the fabrication than other layers of metal patterns 120 (the metal layers126) due to the large thickness and modulus.

In some embodiments, each of the layers of the metal patterns in the semiconductor structure can be fabricated based on given pattern parameters for ensuring the accessibility of the fabrication. Each of the pattern parameters for each of a plurality of metal layers 120 can include the metal density range, the metal thickness range and others for the metal patterns. In some embodiments, each of the pattern parameters can be stipulated within a given range according to the ability of the semiconductor fabrication plant and the accessibility of the fabrication process. In some embodiments, warpage caused during fabrication process is a considerable factor for fabricating a semiconductor device since unwanted warpage usually results in failure and/or poor yield of the fabrication, low quality of the product, etc. The warpage of a semiconductor structure is related to the curvature (1/Ri, Ri: the radius of curvature) of a substrate with each layer of metal patterns formed thereon. In some embodiments, the curvature can be calculated by using the Stoney equation. For example, the warpage of the model structure can be determined/simulated by combining the calculated curvatures for all the layers of metal patterns formed on the wafer substrate based on the Stoney equation. In some embodiments, the warpage is positively related to a coefficient of thermal expansion (CTE) of each layer, a thickness of each layer and a distribution density of each layer in addition to the physical properties of the substrate. In addition, a material with higher modulus and larger thickness is more sensitive to the warpage.

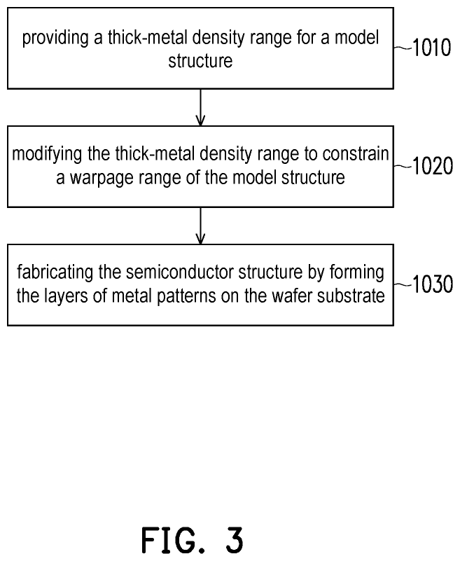

FIG. 3 is schematically flow chart of fabricating a semiconductor structure in accordance with some embodiments. The method 1000 depicted in FIG. 3 may be adopted in fabricating the semiconductor 12 or 14. The method 1000 may include a step 1010 of providing a thick-metal density range for a model structure. In some embodiments, the model structure can include a wafer substrate and layers of metal patterns stacking on the wafer substrate. In some embodiments, the model structure can further include other components and/or layers formed on the wafer substrate for fabricating a semiconductor structure. The layers of metal patterns described in the step 1010 may refer to the layers of metal patterns 120 shown in FIG. 1 and FIG. 2. Herein, the thick-metal density range stipulates the distribution density for the metal patterns of a thick-metal layer among the layers of metal patterns within a given range and the given range may be from a lower thick metal (TM) density value to an upper TM density value. In addition, a thickness of the thick-metal layer is twice or more of a thickness of one of the layers of metal patterns next to the thick-metal layer. For example, the thick-metal density range depicted in the method 1000 refers to the fabrication parameter for the pattern distribution density of the first thick-metal layer 122 or the second thick-metal layer 124 described in FIG. 1 and FIG. 2.

In some embodiments, the warpage range of the model structure is preferably located in a target range of warpage that is from a target lower value to a target upper value. In some embodiments, a negative value of the warpage would possibly result in disadvantage on fabricating the semiconductor device 10 and 30 depicted in FIG. 1 and FIG. 2. For example, the target range of warpage from +50 μm (target lower value) to +250 μm (the target upper value) would facilitate for bonding the semiconductor structure 12 and the semiconductor structure 14 depicted in FIG. 1 and FIG. 2. In the case that the lower value of the warpage range is a negative value or lower than the target upper value, the warpage range is not desirable so that a modification is required, but the disclosure is not limited thereto. In some embodiments, in the case that the lower value of the warpage range is greater than the target lower value, a modification of the warpage range can still be done for design consideration.

In the embodiment, the method 1000 further includes a step 1020 of modifying the thick-metal density range to constrain a warpage range of the model structure. In some embodiments, the constrained warpage range of the model structure is more closer to, meet, or within the target range of warpage. For example, a lower value of the constrained warpage range is closer to the target lower value of the target range of warpage than that before the constraining. In some embodiments, the modification of the thick-metal density range can include increasing the lower TM density value of the thick-metal density range. In some embodiments, the modification of the thick-metal density range can further include decreasing the upper TM density value of the thick-metal density range. In some embodiments, the modification of the thick-metal density range can include decreasing a range size of the thick-metal density range, i.e. constraining the thick-metal density range.

In some embodiments, the thick-metal layer depicted in the method 1000 can be the first thick-metal layer 122 shown in FIG. 1 and FIG. 2, which has a thickness in a range from 8,000 Å to 12,000 Å and high modulus of greater than 100 Gpa. For the first thick-metal layer 122 shown in FIG. 1 and FIG. 2, an increase of 1% in the thick-metal density results in an increase of +3.6 μm in the warpage of the model structure. For the first thick-metal layer 122 shown in FIG. 1 and FIG. 2, the thick-metal density range can be modified by increasing the lower TM density value of the thick-metal density range by ≤125%, e.g. (modified lower TM density value-initial lower TM density value)/initial lower TM density value≤125%. For example, the initial lower TM density value can be 20% and the modified lower TM density value can be 45%, but the disclosure is not limited thereto. For the first thick-metal layer 122 shown in FIG. 1 and FIG. 2, the modification of the thick-metal density range can further include decreasing the upper TM density value of the thick-metal density range by ≤6%, e.g. (modified upper TM density value-initial upper TM density value)/initial upper TM density value≤6%. For the first thick-metal layer 122 shown in FIG. 1 and FIG. 2, the modification of the thick-metal density range constrains a range size of the thick-metal density range by ≤46%, e.g. (initial thick-metal density range size-modified thick-metal density range size)/initial thick-metal density range size≤46%, which provides sufficient room for designing. In some embodiments, the pattern distribution density of the metal layers 126 shown in FIG. 1 and FIG. 2 may be twice or more of the modified lower TM density value of the first thick-metal layer 122 shown in FIG. 1 and FIG. 2

In some embodiments, the thick-metal layer depicted in the method 1000 can be the second thick-metal layer 124 shown in FIG. 1 and FIG. 2, which has a thickness greater than 25,000 Å. For the second thick-metal layer 124 shown in FIG. 1 and FIG. 2, an increase of 1% in the thick-metal density would result in an increase of +4.6 μm in the warpage of the model structure. For the second thick-metal layer 124 shown in FIG. 1 and FIG. 2, the thick-metal density range can be modified by increasing the lower TM density value of the thick-metal density range by ≤20%, e.g. (modified lower TM density value-initial lower TM density value)/initial lower TM density value≤20%. For example, the initial lower TM density value can be 50% and the modified lower TM density value can be about 60%, but the disclosure is not limited thereto. For the second thick-metal layer 124 shown in FIG. 1 and FIG. 2, the modification of the thick-metal density constrains a range size of the thick-metal density range by ≤33%, e.g. (initial thick-metal density range size-modified thick-metal density range size)/initial thick-metal density range size≤33%. For the second thick-metal layer 124 shown in FIG. 1 and FIG. 2, the upper TM density value of the thick-metal density range may be maintained without being modified for ensuring sufficient range size of the thick-metal density range.

In some embodiments, the method 100 further includes the step 1030 of fabricating the semiconductor structure by forming the layers of metal patterns on the wafer substrate based on the modified thick-metal density range. Specifically, the thick-metal layer among the layers of metal patterns is formed based on the modified thick-metal density range. In some embodiments, the layers of metal patterns are formed on the wafer substrate using the method 1000 and the wafer substrate with the layers of metal patterns thereon is cut into a die form to obtain the semiconductor structure 12 or the semiconductor structure 14 depicted in FIG. 1 and FIG. 2. Based on the modified thick-metal density range obtained in the step 1020, the warpage of the wafer substrate with the layers of metal patterns thereon may be controlled to approach or meet the target range of warpage, e.g. from +50 μm to +250 μm, which facilitates the bonding the semiconductor structure 12 to the semiconductor structure 14 depicted in FIG. 1 and FIG. 2.

In some embodiments, the step 1030 of fabricating semiconductor structure can further include forming an upper dielectric layer over the layers of the metal patterns. The upper dielectric layer can be made of silicon nitride. In addition, the warpage range of the model structure described in the step 1020 can be further constrained by modifying a thickness range of the upper dielectric layer. In some embodiments, a prescribed thickness range of the upper dielectric layer is from 5,000 Å to 9,000 Å. In some embodiments, the lower value of the prescribed thickness range of the upper dielectric layer can be decreased to 2,000 Å to 4,000 Å when the warpage range obtained by solely modifying the thick-metal density range is not desirable. In some embodiments, the upper value of the prescribed thickness range of the upper dielectric layer can be increased to 11,000 Å to 15,000 Å when the warpage range obtained by solely modifying the thick-metal density range is not desirable.

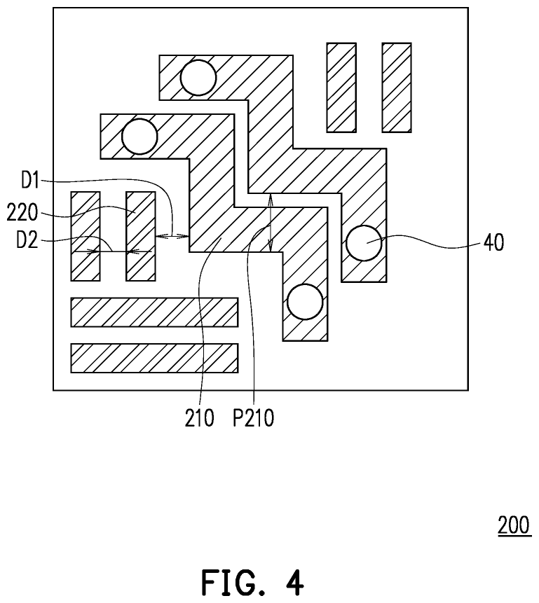

FIG. 4 schematically illustrates a top view of a thick-metal layer in the semiconductor structure in accordance with some embodiments of the disclosure. A thick-metal layer 200 in FIG. 4 can be a metal layer has a large thickness, such as the first thick-metal layer 122 or the second thick-metal layer 124 in FIG. 1 and FIG. 2. The routing of the thick-metal layer 200 can be an implemented example for the first thick-metal layer 122 or the second thick-metal layer 124 in FIG. 1 and FIG. 2 and can be fabricated by using the method 1000 of FIG. 3, but the disclosure is not limited thereto. The thick-metal layer 200 includes electric transmission patterns 210 and dummy patterns 220. The electric transmission patterns 210 are metal patterns that establish electric signal transmission features and the dummy patterns 220 are metal patterns that are electrically floating without transmitting an electric signal. In some embodiments, one or more conductor features 40 such as conductor vias are disposed on the electric transmission patterns 210 to connect the electric transmission patterns 210 to another layer of metal patterns. The conductor features 40 can be disposed under or over the electric transmission patterns 210 in a cross-sectional view to connect the transmission patterns 210 to other layers of metal patterns. However, no conductor features 40 is arranged on the dummy patterns 220.

In some embodiments, the electric transmission patterns 210 of the thick-metal layer 200 may be designed based on an initially given thick-metal density range as depicted in the step 1010 of the method 1000. For example, the electric transmission patterns 210 is arranged to have a distribution density not greater than the lower TM density value of the given thick-metal density range. For meeting the initially given lower TM density value, the dummy patterns 220 are added in the metal layer 200 when the distribution density of the electric transmission patterns 210 is lower than the initially given lower TM density value. As indicated to the step 1020 and the step 1020, in the case that the given thick-metal density range for forming the thick-metal layer 200 requires modification to meet or approach the target range of warpage, the lower TM density value need be increased. Accordingly, the dummy patterns 220 are further added in the thick-metal layer 200 to achieve the desirable pattern density that is located within the modified thick-metal density range, even though the distribution density of the electric transmission patterns 210 is equal to the lower TM density value of the initially given thick-metal density range. In some embodiments, an overall distribution density of the electric transmission patterns 122 and the first dummy patterns 124 is greater than the pattern distribution density of the electric transmission patterns 122 by ≤125% of the pattern distribution density of the electric transmission patterns 122.

In some embodiments, a distance D1 between one of the dummy patterns 220 and an adjacent one of the electrical transmission patterns 210 is ranged from about 0.3 μm to about 0.7 μm, for example, about 0.5 μm and a distance D2 between two adjacent ones of the first dummy patterns 220 is ranged from about 0.3 μm to about 0.7 μm, for example about 0.5 μm. In some embodiments, for the thick-metal layer 200 having a thickness ranged from 8,000 Å to 12,000 Å, a pitch P210 of the electrical transmission patterns 210 can be 700 nm to 2,000 nm. In some embodiments, for the thick-metal layer 200 having a thickness greater than 25,000 Å, a pitch P210 of the electrical transmission patterns 210 can be greater than 720 nm.

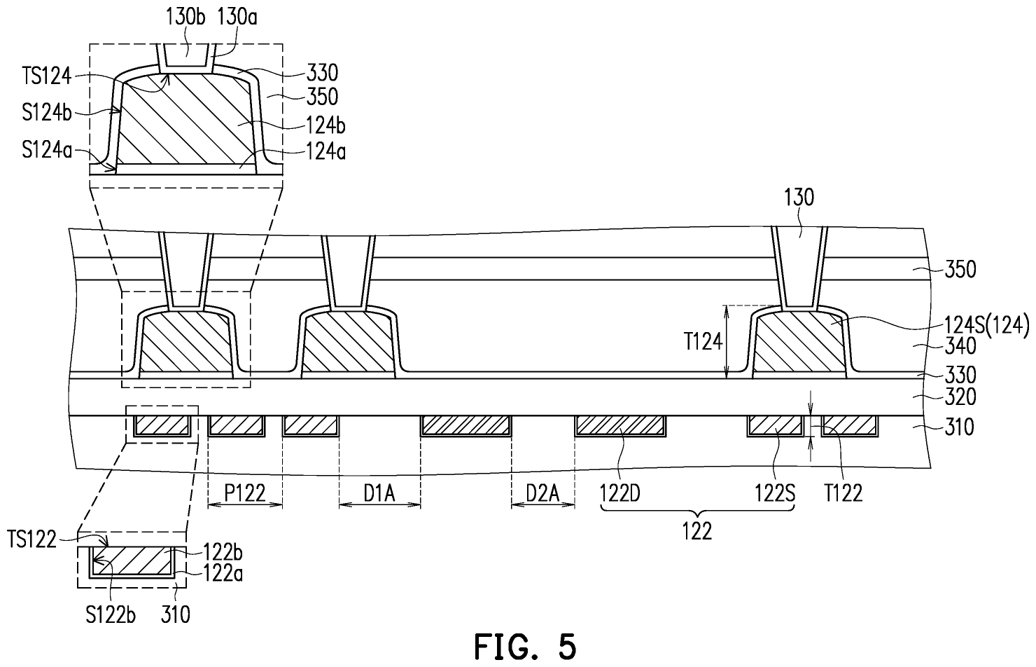

FIG. 5 schematically illustrates a portion of a semiconductor structure in accordance with some embodiments of the disclosure. The structure presented in FIG. 5 is an implemental example for the first thick-metal layer 122 and the second thick-metal layer 124 in the semiconductor structure 12 or 14 depicted in FIG. 1 and FIG. 2 and some components of the semiconductor structure 12 or 14 depicted in FIG. 1 and FIG. 2 are omitted in FIG. 5 for descriptive purpose. As shown in FIG. 5, the first thick-metal layer 122 includes a plurality of first electric transmission patterns 122S and a plurality of first dummy patterns 122D. For descriptive purpose, the first electric transmission patterns 122S in FIG. 5 are filled with single hatching lines and the first dummy patterns 122D in FIG. 5 are filled with double hatching lines. In some embodiments, the first electric transmission patterns 122S and the first dummy patterns 122D are formed embedded in the dielectric structure 310 and are covered by a dielectric layer 320. The second thick-metal layer 124 is disposed on the dielectric layer 320. The second metal layer 124 includes a plurality of second electric transmission patterns 124S arranged over the first thick-metal layer 122. A passivation layer 330 covers the dielectric layer 320 and the second electric transmission patterns 124S in a conformal manner. A polymer layer 340 is disposed over the passivation layer 330 to fill the space between the second electric transmission patterns 124S. In some embodiments, the bonding features 130 (e.g. the bonding vias 134 depicted in FIG. 1 and FIG. 2) is disposed passing through the polymer layer 340 to contact with the second electric transmission patterns 124S. An upper dielectric layer 350 is disposed on the polymer layer 340 over the second thick-metal layer 124. The upper dielectric layer 350 is located over all of the layers of the metal patterns 120 shown in FIG. 1 and FIG. 2.

The dielectric structure 310 can include undoped silica glass (USG) or silicon oxide. The dielectric layer 320 may be formed of silicon nitride and a thickness of the dielectric layer 320 may be ranged from about 2,000 Å to about 11,000 Å, for example bout 15,000 Å. The dielectric layer 320 may include two or more sub-layers collectively referred to as an insulation structure. In some embodiments, one or more passive device (not shown) can be embedded in the dielectric layer 320 between the sub-layers of the dielectric layer 320. The passive device may include a resistor, a capacitor or a diode. In some embodiments, the passive device may include a metal-insulator-metal (MIM) capacitor. The passivation layer 330 may include silicon nitride. The polymer layer 340 may be deposited using spin-on coating and may be formed of a polymeric material, such as polyimide. The upper dielectric layer 350 may be made of the same material as the dielectric layer 320, e.g. silicon nitride. A thickness of the upper dielectric layer 350 is in a prescribed range of 5,000 Å to 9,000 Å.

In some embodiments, the first thick-metal layer 122 is one of the layers of metal patterns 120 depicted in FIG. 1 and FIG. 2 and has a thickness at least twice of a thickness of a next layer of metal patterns 120 such as one layer of the metal patterns 126 underlying the first thick-metal layer 122 in FIG. 1 and FIG. 2. In some embodiments, the thickness T122 of the first thick-metal layer 122 can be from 8,000 Å to 12,000 Å, for example 8,500 Å. In some embodiments, the second thick-metal layer 124 is one of the layers of metal patterns 120 depicted in FIG. 1 and FIG. 2 and has a thickness at least twice of a thickness of a next layer of metal patterns 120 such as the first thick-metal layer 122. In some embodiments, the thickness T124 of the first thick-metal layer 124 can be greater than 25,000 Å, for example 28,000 Å. In some embodiments, the first thick-metal layer 122 and the second thick-metal layer 124 are two thickest layers among the layers of metal patterns 120 depicted in the semiconductor structure 12 or 14 of FIG. 1 and FIG. 2.

The first thick-metal layer 122 shown in FIG. 5 can be fabricated using the method 1000 depicted in FIG. 3. In some embodiments, the first electric transmission patterns 122S may be designed based on the thick-metal density range described in the step 1010 to have a pattern distribution density. In some embodiments, after performing the step of 1020, it may be determined that the calculated warpage is not desirable under the pattern distribution density of the first electric transmission patterns 122S and thus the step 1020 is performed to obtain a modified thick-metal density range. The first thick-metal layer 122 is fabricated by adding the first dummy patterns 122D to meet the modified thick-metal density range. Therefore, an overall distribution density of the first electric transmission patterns 122S and the first dummy patterns 122D is greater than the pattern distribution density of the first electric transmission patterns 122S by ≤125% of the pattern distribution density of the first electric transmission patterns 122S, e.g. (overall distribution density of the first electric transmission patterns 122S and the first dummy patterns 122D—the pattern distribution density of the first electric transmission patterns 122S)/the pattern distribution density of the first electric transmission patterns 122S≤125%.

In the first thick-metal layer 122, the first electric transmission patterns 122S are electrically connected to the second thick-metal layer 124 through conductive vias (not shown) passing through the dielectric layer 320 and the first dummy patterns 122D are metal patterns electrically floating. In some embodiments, the pitch P122 of the first electric transmission patterns 122S can be from 700 nm to 2,000 nm. A distance D1A between one of the first dummy patterns 122D and an adjacent one of the first electric transmission patterns 122S is about 0.5 μm and a distance D2A between two adjacent ones of the first dummy patterns 122D is about 0.5 μm.

In some embodiments, the first thick-metal layer 122 can be one layer in an interconnect structure that is formed by using the same process as the metal layers 126 depicted in FIG. 1 and FIG. 2. Each metal pattern of the first thick-metal layer 124 can include a seed layer 122a having a U-shape structure and a metal fill 122b filling the U-shape structure of the seed layer 122a. In some embodiments, the seed layer 122a and the metal fill 122b can be co-leveled at the top surface TS122 of the metal pattern and the sidewall S122b of the metal fill 122b is isolated from the dielectric structure 310 by the seed layer 122a. In other words, the sidewall S122b of the metal fill 122b is in contact with the seed layer 122a. Each metal pattern of the second thick-metal layer 124 includes a seed layer 124a and a metal feature 124b on the seed layer 124a. The passivation layer 330 is in contact with the sidewall S124b of the metal feature 124b and the sidewall S124a of the seed layer 124a. The metal feature 124b can have a curved top surface TS124. Each bonding features 130b (e.g. the bonding vias 132 depicted in FIG. 1 and FIG. 2.) includes a seed layer 130a having U-shape structure and a metal fill 130b filling the U-shape structure of the seed layer 130a. The bottom portion of the seed layer 130a is in contact with the curved top surface TS124. In some embodiments, one or more liner/barrier layer can be further disposed along the seed layers 122a, 124a and 130a.

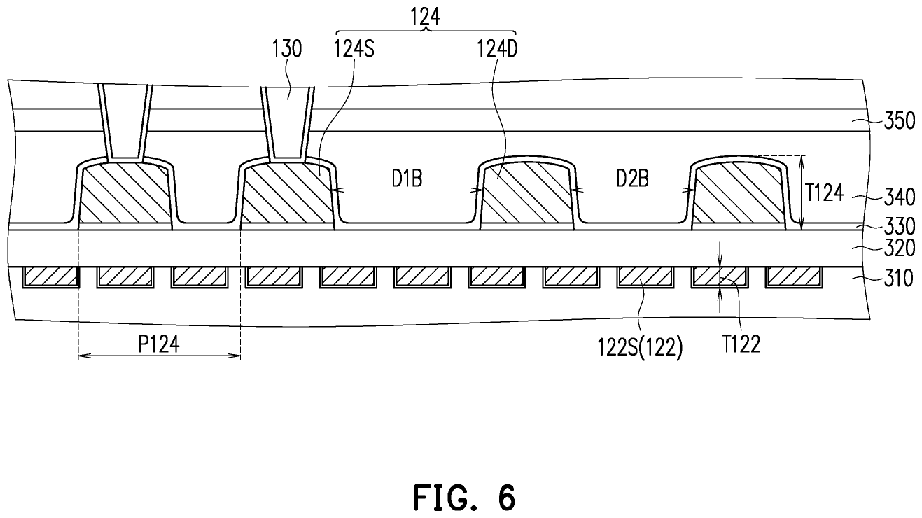

FIG. 6 schematically illustrates a portion of a semiconductor structure in accordance with some embodiments of the disclosure. The structure presented in FIG. 6 is an implemental example for the first thick-metal layer 122 and the second thick-metal layer 124 in the semiconductor structure 12 or 14 depicted in FIG. 1 and FIG. 2 and some components of the semiconductor structure 12 or 14 depicted in FIG. 1 and FIG. 2 are omitted in FIG. 6 for descriptive purpose. In addition, the components described in FIG. 6 are similar to those depicted in FIG. 5 so that the same reference numbers in the two drawings refer to the same or similar components.

In FIG. 6, the first thick-metal layer 122 is embedded in the dielectric structure 310 and includes first electric transmission patterns 122S. The dielectric layer 320 is disposed on the first thick-metal layer 122 with a large thickness such as 15,000 Å. The second thick-metal layer 124 is disposed on the dielectric layer 320 with a thickness T124 that is twice or more than the thickness T122 of the first thick-metal layer 122 next to the second thick-metal layer 124. In some embodiments, the thickness T124 of the second thick-metal layer 124 is greater than 25,000 Å. The passivation layer 330 covers the dielectric layer 320 and the second thick-metal layer 124 in a conformal manner. The polymer layer 340 fills the stagger structure formed by the second thick-metal layer 124. The upper dielectric layer 350 is disposed on the flat surface of the polymer layer 340.

In the embodiments, the second thick-metal layer 124 includes second electric transmission patterns 124S and second dummy patterns 124D. For descriptive purpose, the second electric transmission patterns 124S in FIG. 6 are filled with single hatching lines and the second dummy patterns 124D in FIG. 6 are filled with double hatching lines. The second electric transmission patterns 124S establish signal transmission features and the second dummy patterns 124D are electrically floating. In some embodiments, the second electric transmission patterns 124S are electrically connected to respective bonding features 130 and/or electrically connected to the first electric transmission patterns 122S through conductor features (referring to the conductor features 40 in FIG. 4). The second dummy patterns 124D are isolated from other metal patterns by dielectric materials such as the dielectric layer 320, the passivation layer 330 and the polymer layer 340.

The second thick-metal layer 124 shown in FIG. 6 can be fabricated using the method 1000 depicted in FIG. 3. In some embodiments, the second electric transmission patterns 124S may be designed based on the thick-metal density range described in the step 1010 to have a pattern distribution density. In some embodiments, after performing the step of 1020, it may be determined that the calculated warpage is not desirable under the pattern distribution density of the second electric transmission patterns 124S and thus the step 1020 is performed to obtain a modified thick-metal density range. The second thick-metal layer 124 is fabricated by inserting the second dummy patterns 124D to meet the modified thick-metal density range. Therefore, an overall distribution density of the second electric transmission patterns 124S and the second dummy patterns 124D is greater than the pattern distribution density of the second electric transmission patterns 124S by ≤20% of the pattern distribution density of the second electric transmission patterns 124S, e.g. (overall distribution density of the second electric transmission patterns 124S and the second dummy patterns 124D—the pattern distribution density of the second electric transmission patterns 124S)/initial the pattern distribution density of the second electric transmission patterns 124S≤20%. In some embodiments, a distance D1B between one of the second dummy patterns 124D and an adjacent one of the second electrical transmission patterns 124S is about 0.5 μm and a distance D2B between adjacent two of the second dummy patterns 124D is about 0.5 μm. In some embodiments, the pitch P124 of the second electric transmission patterns 124S can be greater than 720 nm.

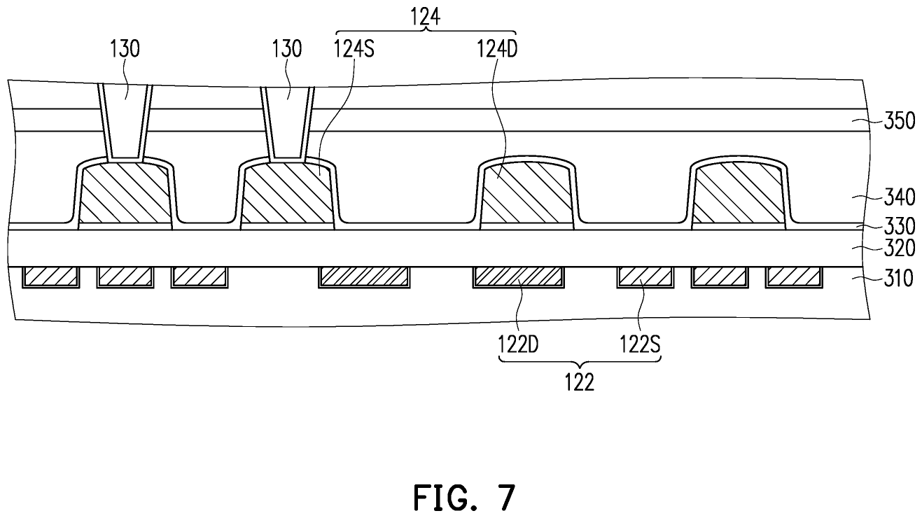

FIG. 7 schematically illustrates a portion of a semiconductor structure in accordance with some embodiments of the disclosure. The structure presented in FIG. 7 is an implemental example for the first thick-metal layer 122 and the second thick-metal layer 124 in the semiconductor structure 12 or 14 depicted in FIG. 1 and FIG. 2 and some components of the semiconductor structure 12 or 14 depicted in FIG. 1 and FIG. 2 are omitted in FIG. 6 for descriptive purpose. In addition, the components described in FIG. 7 are similar to those depicted in FIG. 5 and FIG. 6 so that the same reference numbers in the three drawings refer to the same or similar components.

In FIG. 7, the first thick-metal layer 122 embedded in the dielectric structure 310 includes first electric transmission patterns 122S and first dummy patterns 122D as depicted in FIG. 5. The dielectric layer 320 is disposed on the first thick-metal layer 122 with a large thickness such as 15,000 Å. The second thick-metal layer 124 is disposed on the dielectric layer 320 and includes second electric transmission patterns 124S and second dummy patterns 124D as depicted in FIG. 6. The passivation layer 330 covers the dielectric layer 320 and the second thick-metal layer 124 in a conformal manner. The polymer layer 340 fills the stagger structure formed by the second thick-metal layer 124. The upper dielectric layer 350 is disposed on the polymer layer 340.

In the embodiments, the first thick-metal layer 122 and the second thick-metal layer 124 are fabricated by the method 1000 depicted in FIG. 3. A first overall distribution density of the first electric transmission patterns 122S and the first dummy patterns 122D is greater than the first pattern distribution density of the first electric transmission patterns 122S by ≤125% of the pattern distribution density of the first electric transmission patterns 122S and a second overall distribution density of the second electric transmission patterns 124S and the second dummy patterns 124D is greater than the second pattern distribution density of the second electric transmission patterns 124S by ≤20% of the second pattern distribution density of the second electric transmission patterns 124S.

In some embodiments, when the warpage calculated at the step 1020 of the method 1000 is not desirable, the fabrication parameters of the upper dielectric layer 350 may be further adjusted to achieve desirable stress. For example, fabrication conditions of the upper dielectric layer 350 can be adjusted to increase or decrease the stress of the upper dielectric layer 350. In some embodiments, the prescribed thickness range of the upper dielectric layer 350 can be modified. For example, the lower value of the prescribed thickness range of the upper dielectric layer 350 can be adjusted to set at 2,000 Å to 4,000 Å. For example, the upper value of the prescribed thickness range of the upper dielectric layer 350 can be adjusted to set at 11,000 Å to 15,000 Å. In some embodiments, the upper dielectric layer 350 in FIG. 5 and FIG. 6 may have the modified thickness, for example, greater than 9,000, up to 11,000 Å to 15,000 Å or less than 5,000 Å, as low as 2,000 Å to 4,000 Å.

In view of the above, the method of fabricating a semiconductor structure is provided by modifying the thick-metal density range of one or more thick-metal layer that is to be formed on a wafer substrate. The warpage range taken place during the fabrication would meet or approach a target range of warpage. The method of fabricating a semiconductor structure in accordance with the embodiments improves the accessibility of bonding semiconductor structure. In the semiconductor structure, the thick-metal layer can have dummy patterns to achieve the desirable distribution density of metal patterns. In addition, the modified thick-metal density range in accordance with the embodiments provides sufficient room for designing and improve the accessibility of bonding semiconductor structure.

In accordance with some other embodiments of the disclosure, a method of fabricating a semiconductor structure including providing a thick-metal density range for a model structure, wherein the model structure includes a wafer substrate, and layers of metal patterns stacking on the wafer substrate; modifying the thick-metal density range to constrain a warpage range of the model structure toward a target range of warpage; and fabricating the semiconductor structure by forming the layers of metal patterns on the wafer substrate, wherein a thick-metal layer among the layers of metal patterns is formed based on the modified thick-metal density range, and a thickness of the thick-metal layer is twice or more of a thickness of one of the layers of metal patterns next to the thick-metal layer. The warpage range is constrained by increasing a lower value of the warpage range. The fabricating the semiconductor structure further includes forming an upper dielectric layer over the layers of the metal patterns and the warpage range is further constrained by modifying a thickness range of the upper dielectric layer, the thickness of the thick-metal layer is ranged from 8,000 Å to 12,000 Å and the modifying the thick-metal density range includes increasing a lower thick-metal density value of the thick-metal density range by ≤125%. The modification of the thick-metal density range constrains a range size of the thick-metal density range by ≤46%. The modifying the thick-metal density range includes decreasing an upper thick-metal density value of the thick-metal density range by ≤6%. A thickness of the thick-metal layer is greater than 25,000 Å and the modifying the thick-metal density range includes increasing a lower thick-metal density value of the thick-metal density range by ≤20%. The modifying the thick-metal density range constrains a range size of the thick-metal density range by ≤33%. The target range of warpage is from +50 μm to +250 μm.

In accordance with some other embodiments of the disclosure, a semiconductor structure includes a substrate; and a plurality of layers of metal patterns disposed on the substrate, wherein a first thick-metal layer among the layers of metal patterns has a thickness twice or more of a thickness of a next layer of metal pattern, and the first thick-metal layer includes first electric transmission patterns having a first pattern distribution density; and first dummy patterns, wherein a first overall distribution density of the first electric transmission patterns and the first dummy patterns is greater than the first pattern distribution density by ≤125% of the first pattern distribution density. A distance between one of the first dummy patterns and an adjacent one of the first electrical transmission patterns or the first dummy patterns is about 0.5 μm. Metal patterns in the layers of metal patterns are arranged in a pitch that the pitch of one layer of metal pattern more adjacent to the substrate is smaller than the pitch of another layer of metal pattern further from the wafer substrate. A second thick-metal layer among the layers of metal patterns is disposed on the first thick-metal layer and has a thickness twice or more of the thickness of the first thick-metal layer. The second thick-metal layer includes second electric transmission patterns having a second pattern distribution density; and second dummy patterns, wherein a second overall distribution density of the second electric transmission patterns and the second dummy patterns is greater than the second pattern distribution density by ≤20% of the second pattern distribution density. A distance between one of the second dummy patterns and an adjacent one of the second electrical transmission patterns or the second dummy patterns is about 0.5 μm. A dielectric layer is further disposed between the first thick-metal layer and the second thick-metal layer and a material of the dielectric layer comprises silicon nitride. A thickness of the dielectric layer is 15,000 Å.

In accordance with some other embodiments of the disclosure, a semiconductor structure, includes a substrate; and a plurality of layers of metal patterns disposed on the substrate, wherein a thick-metal layer among the layers of metal patterns has a thickness greater than 20,000 Å, and the thick-metal layer includes electric transmission patterns having a pattern distribution density; and dummy patterns. An overall distribution density of the electric transmission patterns and the dummy patterns is greater than the pattern distribution density by ≤20% of the pattern distribution density. A distance between one of the dummy patterns and an adjacent one of the electrical transmission patterns or the dummy patterns is about 0.5 μm. A dielectric layer is further disposed on the substrate, the thick-metal is disposed on the dielectric layer and a material of the dielectric layer includes silicon nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor structure, comprising:
providing a thick-metal density range for a model structure, wherein the model structure comprises a wafer substrate, and layers of metal patterns stacking on the wafer substrate;
modifying the thick-metal density range to constrain a warpage range of the model structure toward a target range of warpage; and
fabricating the semiconductor structure by forming the layers of metal patterns on the wafer substrate, wherein a thick-metal layer among the layers of metal patterns is formed based on the modified thick-metal density range, and a thickness of the thick-metal layer is twice or more of a thickness of one of the layers of metal patterns next to the thick-metal layer.

2. The method of claim 1, wherein the warpage range is constrained by increasing a lower value of the warpage range.

3. The method of claim 1, wherein the fabricating the semiconductor structure further comprises forming an upper dielectric layer over the layers of the metal patterns and the warpage range is further constrained by modifying a thickness range of the upper dielectric layer.

4. The method of claim 1, wherein the thickness of the thick-metal layer is ranged from 8,000 Å to 12,000 Å and the modifying the thick-metal density range comprises increasing a lower thick-metal density value of the thick-metal density range by ≤125%.

5. The method of claim 4, wherein the modifying the thick-metal density range constrains a range size of the thick-metal density range by ≤46%.

6. The method of claim 4, wherein the modifying the thick-metal density range comprises decreasing an upper thick-metal density value of the thick-metal density range by ≤6%.

7. The method of claim 1, wherein a thickness of the thick-metal layer is greater than 25,000 Å and the modifying the thick-metal density range comprises increasing a lower thick-metal density value of the thick-metal density range by ≤20%.

8. The method of claim 7, wherein the modifying the thick-metal density range constrains a range size of the thick-metal density range by ≤33%.

9. The method of claim 1, wherein the target range of warpage is from +50 μm to +250 μm.

10. A semiconductor structure, comprising:
a substrate; and
a plurality of layers of metal patterns disposed on the substrate, wherein a first thick-metal layer among the layers of metal patterns has a thickness twice or more of a thickness of a next layer of metal pattern, and the first thick-metal layer comprises:
first electric transmission patterns having a first pattern distribution density; and
first dummy patterns, a first overall distribution density of the first electric transmission patterns and the first dummy patterns is greater than the first pattern distribution density by ≤125% of the first pattern distribution density.

11. The semiconductor structure of claim 10, wherein a distance between one of the first dummy patterns and an adjacent one of the first electrical transmission patterns or the first dummy patterns is about 0.5 μm.

12. The semiconductor structure of claim 10, wherein metal patterns in the layers of metal patterns are arranged in a pitch that the pitch of one layer of metal pattern more adjacent to the substrate is smaller than the pitch of another layer of metal pattern further from the wafer substrate.

13. The semiconductor structure of claim 10, wherein a second thick-metal layer among the layers of metal patterns is disposed on the first thick-metal layer and has a thickness twice or more of the thickness of the first thick-metal layer.

14. The semiconductor structure of claim 13, wherein the second thick-metal layer comprises:
second electric transmission patterns having a second pattern distribution density; and
second dummy patterns, a second overall distribution density of the second electric transmission patterns and the second dummy patterns is greater than the second pattern distribution density by ≤20% of the second pattern distribution density.

15. The semiconductor structure of claim 13, wherein a distance between one of the second dummy patterns and an adjacent one of the second electrical transmission patterns or the second dummy patterns is about 0.5 μm.

16. The semiconductor structure of claim 13, further comprising a dielectric layer disposed between the first thick-metal layer and the second thick-metal layer and a material of the dielectric layer comprises silicon nitride.

17. The semiconductor structure of claim 13, wherein a thickness of the dielectric layer is 15,000 Å.

18. A semiconductor structure, comprising:
a substrate; and
a plurality of layers of metal patterns disposed on the substrate, wherein a thick-metal layer among the layers of metal patterns has a thickness greater than 25,000 Å, and the thick-metal layer comprises:
electric transmission patterns having a pattern distribution density; and
dummy patterns, wherein an overall distribution density of the electric transmission patterns and the dummy patterns is greater than the pattern distribution density by ≤20% of the pattern distribution density.

19. The semiconductor structure of claim 18, wherein a distance between one of the dummy patterns and an adjacent one of the electrical transmission patterns or the dummy patterns is about 0.5 μm.

20. The semiconductor structure of claim 18, further comprising a dielectric layer disposed on the substrate, the thick-metal is disposed on the dielectric layer and a material of the dielectric layer comprises silicon nitride.
